(19) United States
(12) Patent Application Publication
(10) Pub. No.: US 2013/0062099 A1
(43) Pub. Date: Mar. 14, 2013

(54) MULTIPLE LAYER Z-AXIS INTERCONNECT APPARATUS AND METHOD OF USE

(71) Applicant: Christopher A. Hunrath, San Juan Capistrano, CA (US)

(72) Inventor: Christopher A. Hunrath, San Juan Capistrano, CA (US)

(73) Assignee: CAC, INC., Lake Forest, CA (US)

(21) Appl. No.: 13/571,229

(22) Filed: Aug. 9, 2012

Related U.S. Application Data
(60) Provisional application No. 61/522,134, filed on Aug. 10, 2011.
(60) Provisional application No. 61/528,113, filed on Aug. 26, 2011.

(51) Int. Cl. H05K 1/02; H01B 13/00; H05K 3/00

(52) U.S. Cl. 174/251; 29/846; 216/18

(57) ABSTRACT

A multiple layered apparatus and method for forming a z-axis interconnect is provided. The multiple layered apparatus comprises a protective layer, a dielectric layer, a conductive layer, and a support layer. A method for forming a z-axis interconnect using the multiple layer apparatus resulting in a thinner and less expensive structure for printed circuit board applications.

### CROSS-REFERENCE TO RELATED APPLICATIONS

This application claims the benefit of priority under 35 U.S.C §119(e) of U.S. Provisional Application No. 61/522,134 filed on Aug. 10, 2011, and entitled “MULTIPLE LAYER Z-AXIS INTERCONNECT APPARATUS AND METHOD OF USE,” and U.S. Provisional Application No. 61/528,113 filed on Aug. 26, 2011, and entitled “PROTECTIVE LAYER FOR PRINTED CIRCUIT BOARD APPLICATIONS” which are hereby incorporated herein by reference in their entirety and are to be considered a part of this specification.

### BACKGROUND

1. Field

The disclosure of the present application generally relates to the fabrication of printed circuit boards.

2. Description of the Related Art

Printed circuit boards (PCB) comprise one or more layers of electrically conductive material such as copper and one or more electrically insulating layers such as dielectric substrates. Multilayer PCBs typically comprise two or more inner and/or surface conductive layers formed over and separated by a plurality of insulating layers and holes, vias, and through holes providing electrical connection between the various inner conductive layers and/or the inner conductive layers and the surface conductive layers.

Holes are drilled in electrical interconnect systems such as printed circuit boards (“PCBs”) for various purposes, including the accommodate component leads, interconnect different layers of PCBs, etc.

Often times, z-axis interconnects or via holes are drilled vertically in between layers of PCBs. These holes allow for electrical connections between the layers. Through laminating multiple drilled layers upon one another, a high density interconnect or “HDI” can be formed. Generally fewer than ten layers may form a HDI because of issues such as processing temperature and weaknesses within the materials comprising the board. Generally, each layer of a HDI PCB contains a copper foil, which is printed to form circuits. The copper foils may then be drilled vertically and plated to form connections.

Several aspects of the PCB manufacturing and assembly processes subject PCB components to mechanical, thermal, physical, chemical and/or electrical strain. For example, manufacturing exposes PCBs to a range of temperatures, including high soldering temperatures which have increased even more in response to the industry's recent adoption of lead-free processes. Strain causes defects in components resulting in electrical and/or mechanical failure; thermal strain arising from increasing temperatures causes cracks in the PCB components, including pad cratering, a type of crack occurring in cap layers, insulating layers that engage surface conductive layers. Improved PCB components capable of enduring strain and resisting damage such as pad cratering are contemplated in the present patent application.

Connections between vertical layers (via the Z-axis) are generally formed in one of two ways. First, copper or nickel may be plated into the drilled holes to form interconnects. An alternative method may include the use of conductive paste or conductive ink to connect between vertical layers of a PCB. Conductive inks usually contain conductive materials such as powdered or flaked silver and carbon like materials. Conductive paste is preferably used with blind vias. The present application provides improved systems for forming interconnected PCB systems.

### SUMMARY

In an embodiment, a HDI PCB apparatus is disclosed including at least one layer of aluminum, at least one layer of copper, at least one dielectric layer and at least one protective layer. The at least one layer of aluminum engages the at least one layer of copper, the at least one layer of copper engages the at least one dielectric layer, and the at least one dielectric layer engages the at least one protective layer.

In another embodiment, a HDI PCB apparatus is disclosed including at least one layer of aluminum, at least one layer of copper, at least one cured dielectric layer, at least one B-stage dielectric layer, and at least one protective layer. The at least one layer of aluminum engages the at least one layer of copper, the at least one layer of copper engages the at least one cured dielectric layer, the at least one cured dielectric layer engages the at least one B-stage dielectric layer, and the at least one B-stage dielectric layer engages the at least one protective layer.

In yet another embodiment, a method for forming a z-axis interconnect is disclosed including providing a z-axis interconnect apparatus comprising at least one first support layer, at least one conductive layer, at least one dielectric layer, and at least one protective layer, drilling a hole through the at least one protective layer and the at least one support layer, filling the hole with a conductive ink, baking the apparatus and the conductive ink, laminating a second apparatus comprising a second conductive layer and a second support layer on the z-axis interconnect apparatus, removing the first support layer and the second support layer, and etching a circuit on the first conductive layer and the second conductive layer.

In yet another embodiment, a method for forming a HDI PCB apparatus includes providing a roll of a support material comprising sheets of the support material, providing a roll of a conductive material comprising sheets of the conductive material, providing a roll of a dielectric material comprising sheets of the dielectric material, providing a roll of a support material comprising sheets of the support material, rolling the sheets of the roll of a support material, the roll of a conductive material, a roll of a dielectric material, and the roll of the support material together to form long sheets of the HDI PCB apparatus, and cutting the long sheets of the HDI PCB apparatus into single sheets of the HDI PCB apparatus.

### BRIEF DESCRIPTION OF THE DRAWINGS

These and other features will now be described with reference to the drawings summarized below. These drawings and the associated description are provided to illustrate one or more embodiments described in the present patent application and not to limit the scope of the disclosed embodiments.

FIG. 1 is a schematic side view of an embodiment of the present application.

FIG. 2 is a schematic top end view of an embodiment of the present application.

FIG. 3 is a schematic side view of an embodiment of the present application.

FIG. 4 is a schematic side view of an embodiment of the present application.

FIG. 5 is a schematic side view of an embodiment of the present application.

FIG. 6 is a schematic side view of an embodiment of the present application.

FIG. 7 is a schematic side view of an embodiment of the present application.

FIG. 8 is a schematic side view of an embodiment of the present application.

FIG. 9 is a schematic side view of an embodiment of the present application.

FIG. 10 is a schematic side view of a method of creating an embodiment of the present application.

### DETAILED DESCRIPTION

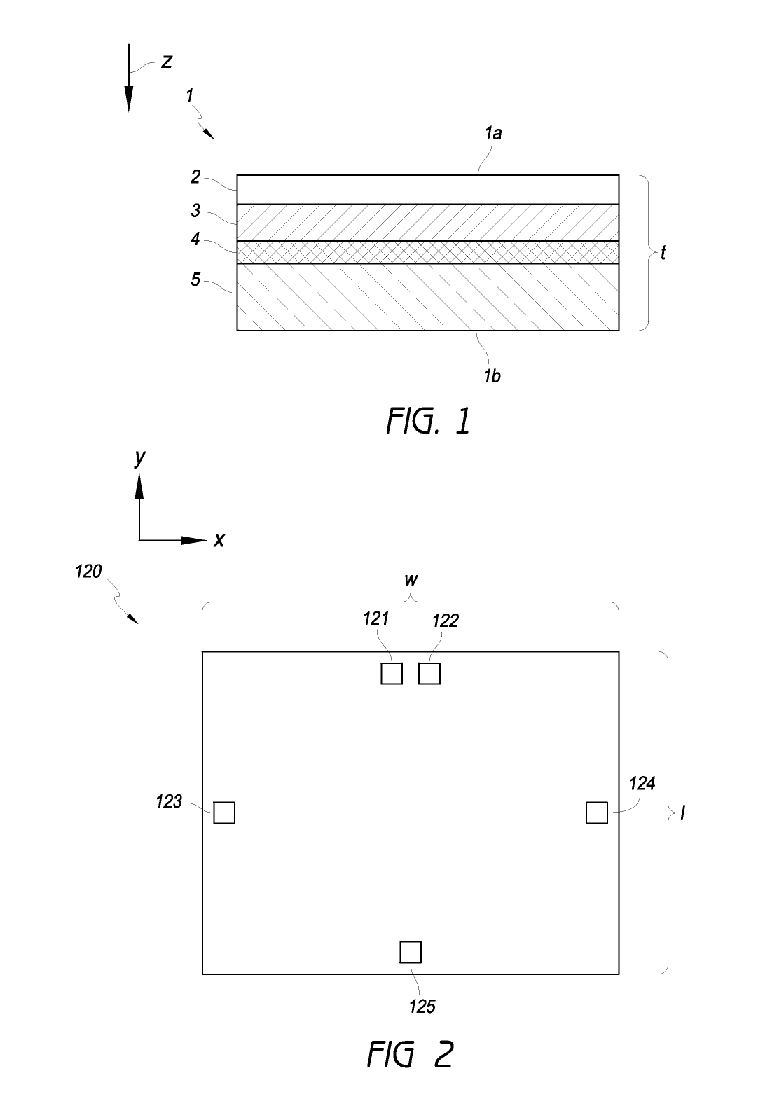

In describing various embodiments of the present invention related to methods, systems and materials for use in printed circuit board drilling applications, reference will be made herein to FIGS. 1-10 of the drawings in which like numerals refer to like features.

### A. Introduction

The terms “printed circuit board,” “PCB” or “electrical interconnect systems” as used in the present patent application are interchangeable and are broadly defined and comprise, without limitation, any and all systems that provide, among others, mechanical support to electrical components, electrical connection to and between these electrical components, or the like. PCBs comprise systems that generally include a base platform to support the electrical components (for example, a thin board of insulating material) and conductors such as conductive pathways, surfaces, solderable attachments, and the like interconnect the electrical components. PCBs can employ a broad range of technologies to support the electrical components (for example, through-hole, surface-mount, mixed-technology, component mounted on one or both sides, etc.) and can comprise a wide range of single or multi-layer or laminate constructions (for example, single-sided, double-sided, multilayer, flexible, rigid-flex, stripline, etc). The terms broadly describe PCBs at any stage of the manufacturing process, including, for example, multiple PCBs configured into a stack structure to be drilled by drilling machines. For the purposes of this disclosure a PCB may include a completed printed circuit board as well as a partially completed circuit board.

As used herein, “protective layer” refers broadly to a protective film made of a thin film material such as a biaxially-oriented polyethylene terephthalate polyester such as the film sold under the trade name Mylar®. In some embodiments, a protective layer may include more than one layer or materials, such as a plastic film with a low-tack pressure sensitive adhesive. However, any plastic or polymeric film may be used.

As used herein, “dielectric” layer or materials are broadly interpreted and include their industry meaning refer to insulating layers and substrates ordinarily used for making printed circuit boards, including rigid PCBs, made from flexible or rigid polymeric materials. Rigid materials may include, for example, resin, and include, without limitations, materials that are typically reinforced with fiber glass, papers, cotton fabric, asbestos sheet, glass in various forms such as cloth and continuous filament mat, ceramic material, molybdenum, other types of plastic, etc. However, dielectric materials be made of a one or more thermoplastic and/or thermoset polymeric materials without reinforcement. Several other materials or mixtures of materials can be used to produce rigid layers, including “prepreg” or “prepregs” (short for preimpregnated) such as, for example, flame retardant (FR) 2 (cellulose paper impregnated with phenolic resin), FR-3 (cotton paper impregnated with epoxy), FR-4 (epoxy-resin impregnated woven glass cloth), FR-5 (woven glass impregnated with epoxy), etc. PCB dielectric layers as used in this patent application are broadly defined and generally are configured to resist or substantially resist the flow of electricity for, among others, conductive layers and electrical components. Dielectric layers may include a single ply or multiple plys of a polymeric film. Dielectric layers, given their polymeric composition, may be flexible or rigid, based on their composition and their state of cure. For example, a cured or “C-stage” dielectric may be rigid or substantially rigid, while a uncured “A-Stage” or partially cured “B-stage” dielectric may be flexible.

As used herein, “curing” or “cured” or “cure” as used in the present patent application, are broad terms, shall have their ordinary meaning in the industry and are broadly defined and includes, without limitation, the process of polymerizing, toughening and/or hardening polymer material by combining polymers such as thermosets with curing agents or by subjecting polymers to other curing processes such as heat, pressure, radiation, or the like. “Curing agents” or “curing materials” broadly defines substances or mixtures of substances added to polymer materials to promote or control the curing process. Curing agents may comprise non-curing substances. Polymer material can be uncured, partially cured in which the hardening process has begun but is not complete, or fully cured wherein the thermoset resin in the polymer material has substantially or completely hardened. As used herein, “A-stage” materials shall have their ordinary meaning in the industry, and include polymeric materials with no degree of curing. “B-stage” materials shall have their ordinary meaning in the industry, and include polymeric materials that are partially cured. “C-stage” materials shall have their ordinary meaning in the industry, and include polymer materials that are completed cured. Polymer material may also includes mixtures of polymeric materials in various levels of cure. For example, mixtures of polymeric materials may include some A stage of a first type of a thermoset polymeric material and some B-stage of a second type of thermoset polymeric material. In other embodiments, mixtures of polymeric materials may include some B-stage of first type of a thermoset polymeric material and some C-stage of a second type of thermoset polymeric material. In other embodiments, mixtures of polymeric materials may include some A-stage of first type of a thermoset polymeric material and some C-stage of a second type of thermoset polymeric material. In other embodiments, mixtures of polymeric materials may include some A-stage of first type of a thermoset polymeric material and some B-stage of a second type of thermoset polymeric material.

As used herein, “copper” refers broadly to copper and its alloys.

As used herein, “aluminum” refers broadly to aluminum and its alloys.

As used herein, “sintering” or “sintered” as used in the present patent application, are broad terms, shall have their ordinary meaning in the industry and are broadly defined and comprise, without limitation, the process of making objects from a powder through processes such as heat, pressure, radiation, or the like. Generally a material is sintered when it is heated below its melting point until the particles partially or substantially adhere to each another.

The term “layer” is used broadly herein and includes its standard meaning in the industry. The term “layer” implies a position in the cross section (profile) of PCBs or components of PCBs. A layer in a PCB may be continuous or discontinuous, or may or may not be planar or substantially planar. A layer in a PCB may comprise a single ply of a material, or it may include multiple plys of the same material or different materials making up the same layer. For example, a PCB may comprise an inner or outer conductive discontinuous layer such as an etched printed circuit layer. As used in connection with one PCB layer in connection with another PCB layer, the term “engage” is broadly defined to describe a layer or portions of the layer directly or indirectly connected or attached to another layer or portions of the other layer. Non-limiting examples of an indirect connection include, for example, a layer in a PCB connected or attached to another layer through an intermediate layer, such as, for example, an adhesive, a mask, a coating layer, a thin film, a bonding film, and the like. Similarly, “forming,” “depositing,” “positioning” or “providing” as used herein in connection with creating or positioning one layer over or on another layer generally discloses arranging or creating PCB layers such that at least portions of one layer are directly or indirectly engaging the other layer.

“Cap layer,” as used herein, is broadly defined and describes dielectric substrates and insulating layers that interface with or engage the outermost conductive layers, also referred to herein as “surface conductive layers”, such as, for example, surface copper pads. “Surface conductive layer,” “outer conductive layer” or “surface layer” used in connection with PCB conductive layers broadly refer to the outermost conductive layers of PCBs, such as, for example, surface copper layers and etched surface conductive pads generally configured to engage electrical devices mounted on the PCBs, such as, for example, electrical components. “Electronic” or “electrical” components broadly define any PCB-mountable device capable of handling electricity for which PCBs are designed to provide, among others, physical support and/or electrical connection and without limitation include electrical devices, electronic devices, electronic circuits, electrical elements, integrated circuits, hybrid systems, or the like.

As used herein, the terms “pre-form” or “pre-forming” PCB layer components or layers to be used with PCBs as used in the present patent application, are broad terms, shall have their ordinary meaning in the industry and are broadly defined and comprise a discontinuity between manufacturing the components and manufacturing PCBs using the pre-formed components such that the component manufacturing and the PCB manufacturing qualify as “independent manufacturing processes.” A non-limiting example of independent manufacturing processes includes manufacturing PCBs using a component manufactured by an entity different from the entity manufacturing the PCBs, such as, without limitation, 3^{rd} parities (e.g. original equipment manufacturers, distributers, wholesalers, discount sellers, suppliers, retailers, etc.), affiliates, subsidiaries, parent entities, licensors/licensees, other legally different entities, and/or the like. PCB “manufacturing” is broadly defined herein and includes all stages of the PCB manufacturing and assembly process, including, for example, preparing or obtaining materials to make PCB layers, providing at least a first PCB layer, processing one or more PCB layers to form circuit patterns separated by insulating layers, assembling a PCB by mounting an electrical component onto a partially, substantially or fully completed PCB, testing a PCB assembly package comprising electric devices mounted thereon, etc.

The terms “laminate,” “lamination,” and “laminated,” is used with its ordinary meaning and includes, when used in making a PCB or HDI PCB includes the process step wherein cores are placed into a lamination press and heat and pressure are applied. When these terms are used in the context of forming a HDI PCB apparatus, lamination may refer to using a nip roller or a heated or cool roller system to apply some heat and pressure to the layers of a HDI PCB apparatus to allow dielectric materials and/or a protective layer to flow to adhere layers of the HDI PCB apparatus together.

The terms “approximately”, “about”, and “substantially” as used herein represent an amount close to the stated amount that still performs a desired function or achieves a desired result. For example, the terms “approximately”, “about”, and “substantially” may refer to an amount that is within less than 10% of, within less than 5% of, within less than 1% of, within less than 0.1% of, and within less than 0.01% of the stated amount.

### B. General Description of Non-Limiting Embodiment

According to an embodiment, an apparatus is described that uses multiple materials to create a HDI PCB.

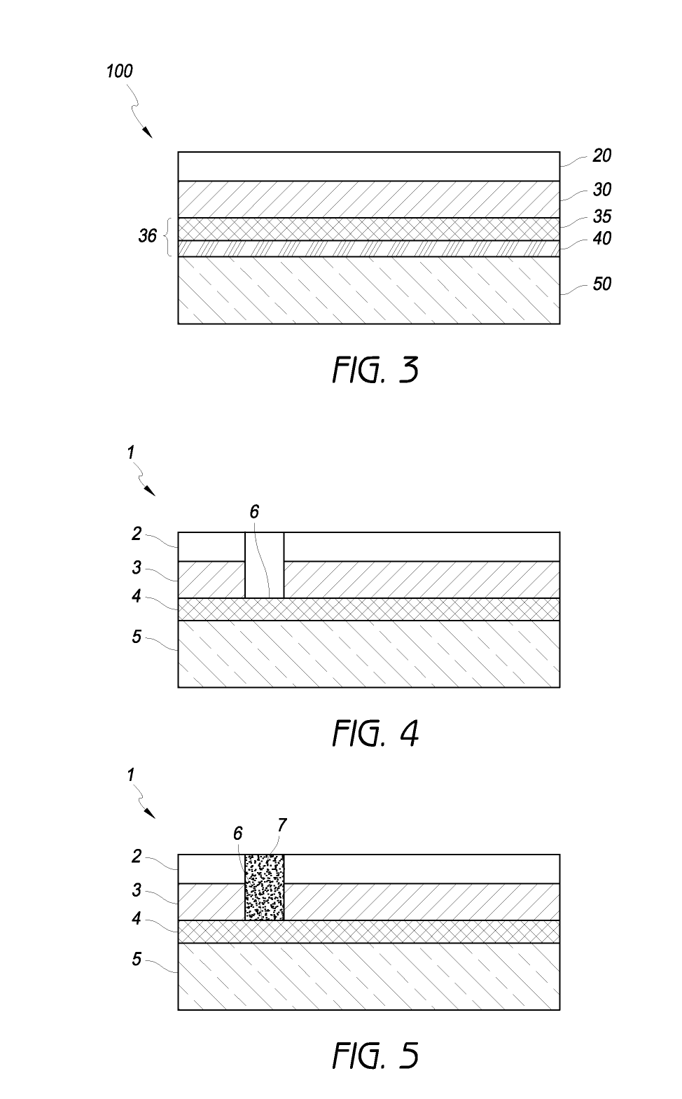

Generally speaking, a PCB and each of its respective layers may include a top surface and a bottom surface. With reference to FIG. 1, the top surface la of a HDI PCB apparatus 1 is generally opposite the bottom surface lb of the HDI PCB apparatus 1, and the top surface la is parallel to the top of the page. Each individual layer illustrated in FIG. 1 and FIG. 3 also comprises a top surface and a bottom surface. Each HDI PCB apparatus may have a thickness t as shown in FIG. 1 along the Z-axis. Each HDI PCB apparatus may also have a width w and a length 1 as shown along the X-axis and Y-axis, respectively in FIG. 2. Each individual layer of the HDI PCB apparatuses illustrated in FIG. 1 and FIG. 3 also has its own width, length, and thickness along the X-axis, Y-axis, and Z-axis respectively.

As shown in FIG. 1 in cross section, according to an embodiment, a HDI PCB apparatus 1 comprises a protective layer 2 disposed on a dielectric layer 3. The dielectric layer 3 is disposed on a conductive layer 4. The conductive layer 4 is disposed on a support layer 5. The layers may be connected to one another by lamination under pressure and/or heat and/or via a suitable adhesive.

The protective layer 2 may comprise one or multiple layers of a protective material designed to protect the other layers of the HDI PCB apparatus from dirt, dust, or debris during storage and/or drilling.

The dielectric layer 3 may comprise one or more layers of dielectric material. In some embodiments, the dielectric layer 3 may be only partially cured, not cured at all, fully cured, or a mixture of dielectric materials in various states of cure.

A conductive layer 4 may comprise one or more layers of a conductive material such as copper. According to some embodiments, a layer of zinc is disposed on the top surface and/or the bottom surface of the conductive layer 4.

The support layer 5 may comprise may comprise one or more layers of a supporting material that may act as a carrier for the other layers in the HDI PCB apparatus 1, such as aluminum.

### C. Detailed Descriptions of Non-Limiting Embodiments

Described herein are improved HDI PCB apparatuses for the manufacture of PCBs including HDI components. The HDI PCB apparatuses described have advantages including, but not limited to, reduction in thinness of PCB layers, reduction of necessary lamination cycles, and reduced cost.

With reference now to FIG. 1, the HDI PCB apparatus 1 is illustrated. As illustrated in FIG. 1, the first protective layer 2 is provided over the dielectric layer 3, the latter of which is provided over the conductive layer 4. The conductive layer 4 is provided over the support layer 5. The top surface of the support layer 5 engages the bottom surface of the conductive layer 4. The top surface of the conductive layer 4 engages the bottom surface of the dielectric layer 3. The top surface of the dielectric layer 3 engages the bottom surface of the protective layer 2.

According to some embodiments, each individual layer of the HDI PCB apparatus 1 has roughly the same length and width as the other layers, and the layers may only vary in thickness. According to some embodiments, each layer of the HDI PCB apparatus 1 comprises a continuous layer or film of material or materials with no circuits etched on the dielectric layer 3.

According to other embodiments, each layer of the HDI PCB apparatus comprises a continuous layer or film of material, except for a tooling hole or tooling holes drilled through all layers of the HDI PCB apparatus. As illustrated in the embodiment of FIG. 2, tooling holes 121, 122, 123, 124 are located near the edge of a single sheet of a HDI PCB apparatus 120.

The first protective layer 2 may comprise any suitable protective material, designed to prevent dirt and debris from contacting any other layer in HDI PCB apparatus 1 during storage, drilling, or any other processing. The first protective layer 2 may be made of materials such as polyethylene terephthalate. The first protective layer 2 may be discardable, that is, the first protective layer 2, may be easily peeled off of the HDI PCB apparatus during subsequent processing steps without leaving any residue on the dielectric layer 3.

In some embodiments the first protective layer 2 also includes an adhesive layer that may bond the first protective layer 2 to the dielectric layer 3. In such an embodiment, the adhesive layer engages the bottom surface of the first protective layer 2 and the top surface of the dielectric layer 3. In some embodiments, no additional adhesive layer exists between the protective layer 2 and the dielectric layer 3.

The first protective layer 2 may comprise a suitable thickness. For example, the protective layer 2 may comprise a thickness between about 0.0007 inches (or about 0.0007 inches) and 0.003 inches (or about 0.003 inches). In some embodiments, the first protective layer 2 may comprise a thickness of between 0.0010 inches (or about 0.0010 inches) and 0.0020 inches (or about 0.0020 inches). In some embodiments, the first protective layer 2 may comprise a thickness of 0.0015 inches (or about 0.0015 inches).

The dielectric layer 3 may comprise any suitable material or combination of materials, namely material that either is cured, or may be cured in a later processing step to form a PCB substrate. In some embodiments, the dielectric layer 3 is a film or multiple layers of films. In some embodiments, the dielectric layer is directly coated on to the first protective layer 2 and/or the conductive layer 4. The dielectric layer 3 may comprise one material or a combination of materials, include one or more of prepreg materials, thermoplastic materials, and/or thermoset materials. The dielectric layer 3, if thermoset, may be cured into a C-stage material may serve as a substrate in a PCB, once the PCB is formed.

In some embodiments, the dielectric layer 3 may comprise one or more of a prepreg such as epoxy FR-4 prepreg (such as FR406 from Isola or 4000-6 from Nelco), phenolic epoxy prepreg (such as 370HR or 185HR from Isola or 4000-29 from Nelco), polyimide prepreg (such as P-95 from Isola or 7000-1 from Nelco), cyanate ester prepreg (such as V-376 from Park), 2113 glass type, 1080 glass type prepreg, and the like. In some embodiments, only one ply or sheet of a prepreg is used in the dielectric layer.

In some embodiments dielectric layer 3 may comprise a thermoplastic material such as polyolefins, polytretafluoroethylene (such as TEFLON® film such as FEP available from DuPont), co-polymers of any of the above, and the like.

In some embodiments, dielectric layer 3 may comprise one or more of a thermoset polymer that is not part of a prepreg, such as epoxy resins as film (such as JADE™ available from Rogers and/or ESPANEX™ available from Nippon Steel Chemical Group), phenoxy resins, benzoxazine resins (such as Benzoxazine 99110 available from Henkel), acrylic film (such as PYRALUX® LF available from DuPont) copolymers of any of the above (such as ZETA BOND SE® film available from Integral) and the like. Some examples of suitable materials for the dielectric layer may be found in U.S. patent application Ser. No. 13/309,513 entitled “IMPROVED ADHESIVE FILM LAYER FOR PRINTED CIRCUIT BOARD APPLICATIONS” filed on Dec. 1, 2011 the specification of which is incorporated by reference herein in its entirety. Data Sheets, technical specifications, and testing results of the aforementioned materials suitable for use alone or in combination as the dielectric layer 3 (e.g. ISOLA® FR406, ISOLA® 370HR, ISOLA P-95, V-376, FEP™, PYRALUX LF™, JADE®, ESPANEX™, and ZETA® BOND SE) are herein incorporated by reference as a part of this specification. In some embodiments, only one ply or sheet of a thermoset material alone is used in the dielectric layer 3. In some embodiments, more than one ply or sheet of a thermoset material is used in the dielectric layer 3.

In some embodiments, a dielectric layer 3 may include a polymeric material that is not yet completed cured. For example, the dielectric layer 3 may include an A-stage or B-stage polymeric material or materials. In such embodiments, the dielectric layer 3 may be further cured or completed cured until later processing methods. In such embodiments, the dielectric layer 3 may not be capable of supporting the other layers of the HDI PCB apparatus 1 by itself. However, in some embodiments, a combination of partially or fully cured thermoset polymer may be included in the dielectric layer 3 along with uncured or only partially cured thermoset polymer. In an embodiment, a dielectric layer may include a hybrid of both uncured or partially cured thermoset materially and fully cured thermoset materials. For example, a dielectric layer 3 may include about 50% by weight of a fully cured epoxy resin and about 50% by weight of an uncured benzoxazine resin, based on the total weight of the dielectric layer. For example, in an embodiment, a dielectric layer may comprise about 25% by weight of a fully cured epoxy resin and about 75% by weight of an uncured benzoxazine resin, based on the total weight of the dielectric layer.

According to another embodiment, a dielectric layer 3 may comprise an amount of cured and/or uncured benzoxazine resin with or without at least one additive, such as a plasticizer. In some embodiments a dielectric layer may include both cured and uncured benzoxazine resin. For example, a dielectric layer 3 may comprise an uncured benzoxazine resin present in an amount in the range of 75% by weight to 95% by weight based on the total weight of the composition and an uncured phenoxy resin present in the composition in an amount in the range of 5% by weight to 25% by weight based on the total weight of the dielectric layer 3. The uncured benzoxazine resin may be present in an amount of about 85% or about 80% based on the total weight of the dielectric layer 3. The dielectric layer 3 may also comprise an amount of cured benzoxazine resin. The cured benzoxazine resin may be present in the composition in an amount in the range of 5% by weight to 25% by weight based on the total weight of the composition of the dielectric layer. The cured benzoxazine resin may also be present in an amount of 5% by weight to 10% by weight, 10% by weight to 20% by weight, 15% by weight to 25% by weight, 20% by weight to 25% by weight, and the like. According to some embodiments, the dielectric layer 3 is substantially all uncured and/or cured benzoxazine resin (95%-100% by weight based on the total weight of the composition of the dielectric layer).

The amount of a polyester-based plasticizer by weight, based on the total weight of the dielectric layer 3, if used, may vary. According to an embodiment, the weight percentage of polyester-based plasticizer may comprise between about 0% and about 25% by weight of the total dielectric layer composition weight. According to other embodiments, the weight percentage of polyester-based plasticizer may comprise between about 5% and about 20% by weight, between about 10% and about 20% by weight, between about 5% and about 10% by weight, and the like, based on total weight of the dielectric layer composition.

In some embodiments, one or more inorganic fillers may be added to the dielectric layer composition. The filler may include calcium carbonate, mica, talc, silicon dioxide, and the like. According to some embodiments, filler, if filler is used, comprises between about 5% by weight and about 40% by weight of the dielectric layer 3, based on the total weight of the dielectric layer 3. In some embodiments, the filler comprises between about 25% by weight and about 40% by weight of the dielectric layer 3.

The dielectric layer 3 may desirably include materials having favorable thermal properties for PCB applications. For example, if a dielectric layer comprises a thermoset and/or a prepreg including a thermoset polymer, the cure temperature of the material or mixture of materials may be in the range of between 150° C. (or about 150° C.) and 350° C. (or about 350° C.). In some embodiments, the cure temperature of the material or mixture of materials may be in the range of between 170° C. (or about 170° C.) and 260° C. (or about 260° C.).

The dielectric layer 3 may also desirably include materials having a glass transition temperature (“Tg”) in the range of between 120° C. and 350° C. In some embodiments, the material or materials comprising the dielectric layer 3 may have a Tg in the range of between 120° C. and 180° C., 160° C. and 350° C., 170° C. and 180° C., and the like. The dielectric material or materials making up dielectric layer 3 may have a Tg greater than 100° C., preferably greater than 170° C.

In some embodiments the dielectric layer 3 also includes an adhesive layer that may bond the dielectric layer 3 to the conductive layer 4. In such an embodiment, the adhesive layer engages the bottom surface of the dielectric layer 3 and the top surface of the conductive layer 4. In some embodiments, no additional adhesive layer exists between the dielectric layer 3 and the conductive layer 4.

According to some embodiments, a dielectric material or materials may be selected for a dielectric layer 3 having favorable electrical properties for the manufacture and use of PCBs. For example, the material or materials making up the dielectric layer may have a dielectric constant in the range of between 2.5 and 4.2 (or about 2.5 and about 4.2). In some embodiments, the material or materials making up the dielectric layer may have a dielectric constant between 3.8 and 4.2 (or about 3.8 and about 4.2) or between 2.5 and 3.8 (or about 2.5 and about 3.8). The material making up the dielectric layer may also exhibit a dissipation factor in the range of between 0.004 and 0.03 (or about 0.004 and 0.03). In some embodiments, the material or materials making up the dielectric layer may have a dissipation factor in the range of between 0.01 and 0.03 (or about 0.01 and about 0.03) or between 0.01 and 0.02 (or about 0.01 and about 0.02).

The dielectric layer 3 may comprise a suitable thickness. For example, the dielectric layer 3 may comprise a thickness between about 0.0008 inches (or about 0.0008 inches) and 0.008 inches (or about 0.008 inches). In some embodiments, the dielectric layer 3 may comprise a thickness of between 0.008 inches (or about 0.008 inches) and 0.004 inches (or about 0.0020 inches). In some embodiments, the dielectric layer 3 may comprise a thickness of 0.0015 inches (or about 0.0035 inches). In embodiments where a prepreg material is used as the dielectric layer 3, a thickness in the range of between 0.002 inches (or about 0.002 inches) and 0.008 inches (or about 0.008 inches) may be used. In embodiments where a prepreg is not used, and instead a polymeric material such as a thermoset and/or thermopolymer is used, the dielectric layer 3 may have a smaller thickness, for example, between 0.0008 inches (or about 0.0008 inches) and 0.004 inches (or about 0.004 inches). For example, a dielectric layer comprising a benzoxazine-phenoxy copolymer may have a thickness of between 0.0008 inches and 0.004 inches.

The conductive layer 4 may comprise any suitable conductive material such as copper. A copper used in conductive layer may include electrodeposited copper and/or roll-annealed copper.

In some embodiments the conductive layer 4 also includes an adhesive layer that may bond the conductive layer 4 to the support layer 5. In such an embodiment, the adhesive layer engages the bottom surface of the conductive layer 4 and the top surface of the support layer 5. The adhesive may comprise a flexible, water soluble adhesive, such as the types of adhesive and method of administering such adhesives disclosed in U.S. Pat. No. 6,048,430, filed Feb. 3, 1999, entitled “Component of Printed Circuit Boards,” the entirety of which is hereby incorporated by reference. In some embodiments, no additional adhesive layer exists between the conductive layer 4 and the support layer 5.

The conductive layer 4 may comprise a suitable thickness. For example, the conductive layer 4 may comprise a thickness between about 5 microns and 80 microns. In some embodiments, the conductive layer 4 may comprise a thickness of between 15 microns (or about 15 microns) and 60 microns (or about 60 microns), between 15 microns (or about 15 microns) and 50 microns (or about 50 microns), between 10 microns (or about 10 microns) and 30 microns (or about 30 microns) and the like. In some embodiments, the conductive layer 4 may comprise a thickness of about 35 microns.

The conductive layer 4 may comprise a suitable amount of a conductive material. For example, in some embodiments, the conductive layer 4 may include between 0.10 oz (or about 0.10 oz) and 0.50 oz (or about 0.50 oz) of a conductive material. The conductive layer 4 may include 0.25 oz (or about 0.25 oz) of a conductive material.

The support layer 5 may provide structural support for the other layers of the HDI PCB apparatus 1. The support layer 5 may comprise a suitable material such as aluminum or steel, nickel, magnesium, a C-stage polymeric material, and the like. Advantageously the support layer 5 has high thermal conductivity and low density. The support layer may prevent the conductive layer 4 from wrinkling and forming defects in the conductive layer 4 through handling, processing, and storage.

The support layer 5 may comprise a suitable thickness. For example, the support layer 5 may comprise a thickness between about 0.003 inches (or about 0.003 inches) and 0.02 inches (or about 0.02 inches). In some embodiments, the support layer 5 may comprise a thickness of between 0.005 inches (or about 0.005 inches) and 0.001 inches (or about 0.001 inches). In some embodiments, the support layer 5 may comprise a thickness of 0.007 inches (or about 0.007 inches).

In one exemplary embodiment, a HDI PCB apparatus was constructed comprising a protective layer of polyethylene terephytlate having a thickness of about 0.0015″, a dielectric layer of a single ply of B-stage 1080 prepreg having a thickness of 0.0035 inches, a conductive layer of copper having a thickness of about 18 microns, and a support layer of aluminum having a thickness of 0.007 inches.

According to another example, a HDI PCB apparatus was constructed comprising a protective layer of polyethylene terephthalate having a thickness of about 0.0015″, a dielectric layer of a single sheet of benzoxazine-phenoxy film having a thickness of about 0.001 inches, a conductive layer of copper having a thickness of about 35 microns, and a support layer of aluminum having a thickness of 0.007 inches.

With reference now to FIG. 3, an alternate embodiment of the HDI PCB apparatus 100 is illustrated. As illustrated in FIG. 3, the first protective layer 20 is provided over the dielectric layer 30, the latter of which is provided over a C-stage layer 35. The C-stage layer 35 is provided over a conductive layer 40. The C-stage layer 35 and the conductive layer 40 make up a cap layer 36. The conductive layer 40 is provided over the support layer 50. The top surface of the support layer 50 engages the bottom surface of the conductive layer 40. The top surface of the conductive layer 40 engages the bottom surface of the C-stage layer 35. The top surface of the C-stage layer 35 engages the dielectric layer 30. The top surface of the dielectric layer 30 engages the bottom surface of the protective layer 20.

The HDI PCB 100 includes an intermediate cap layer 36 comprising the conductive layer 40 and C-stage layer 35. The C-stage layer 35 may include strain resistant layers comprising a high performance thermoset material, such as a polyimide. HDI PCB embodiments can suitably comprise strain resistant layers having different mixtures of polyimide or strain resistant layers made from other strain resistant materials such as, for example, liquid crystal polymer. In one embodiment, strain resistant layers comprising a different mix of polyimide and/or other materials. Further non-limiting examples of strain-resistant cap layers are disclosed in U.S. Pat. No. 8,188,373 entitled “IMPROVED INSULATING LAYER FOR RIGID PRINTED CIRCUIT BOARDS” filed on Dec. 5, 2008, which is hereby incorporated by reference in its entirety.

In accordance with other embodiments disclosed herein, the strain resistant layers comprising polyimide further have favorable properties that may minimize pad cratering failures. In particular strain resistant C-stage layers 35 may comprise polyimide having higher glass transition temperatures in the range of 220-420° C., including 240° C., 290° C., 340° C., 390° C., 440° C., and 490° C., versus roughly 170° C. and 180° C. for standard FR-4 epoxy and high-temp FR-4 Epoxy respectively. The total expansion due to temperature up to solder reflow temperature is lower for a material having higher glass transition temperature range (for example polyimide) than a material having a lower glass transition temperature (for example FR-4 epoxy). Further, materials with higher glass transition temperatures are generally favored for use as insulating layers, including for use as cap layers in rigid PCBs, because such materials maintain their dimensional stability over a wider temperature range, potentially reducing the likelihood that cracks occur in the laminate.

The C-stage layer 36 may comprise a suitable thickness. For example, the C-stage layer 35 may comprise a thickness between about 5 microns (or about 5 microns) and 50 microns (or about 50 microns). In some embodiments, the C-stage layer 35 may comprise a thickness of between 10 microns (or about 10 microns) and 40 microns (or about 40 microns). In some embodiments, the C-stage layer 35 may comprise a thickness of 12 microns (or about 12 microns), 24 microns (or about 24 microns), or 38 microns (or about 38 microns).

The other layers of the HDI PCB apparatus 100 (i.e., the protective layer, the dielectric layer, the conductive layer, and the support layer) may include materials, thicknesses, and properties as described elsewhere in this application.

In one exemplary embodiment, a HDI PCB apparatus was constructed comprising a protective layer of polyethylene terephytlate having a thickness of about 0.0015″, a dielectric layer of a single ply of B-stage 1080 prepreg having a thickness of 0.0035 inches, a C-stage layer of a polyimide film having a thickness of 24 microns, a conductive layer of copper having a thickness of about 12 microns, and a support layer of aluminum having a thickness of 0.007 inches.

In some embodiments, a supplemental protective layer may be adhered to subassemblies of the HDI PCB apparatus after they are drilled and vias are formed, but before they are fully formed into PCBs.

### D. Methods of Manufacture

### Manufacture of an HDI PCB Apparatus

A HDI PCB apparatus like that shown in FIG. 1 may be formed according to the following method. First two or more rolls of sheets or films of material making up the layers of the HDI PCB apparatus are laminated together through hot and/or cold pressure rollers to form a multiple layered system. The hot pressure rollers used may include nip rollers. In some embodiments, all layers making up the HDI PCB apparatus may be combined into a single HDI PCB apparatus after all layers are wound simultaneously through the hot and/or cold pressure rollers. In some embodiments, hot or heated pressure rollers may be used such as nip rollers. FIG. 10 illustrates a method for preparing an HDI PCB apparatus.

The temperature of the hot or cold rollers may be limited so that the dielectric layer does not begin to cure undesirably. According to some methods, if used, the hot pressure rollers nor the cold pressure rollers (if used) do not heat any layer or layers of the HDI PCB apparatus above 150° C. According to some methods, if used, the hot pressure rollers nor the cold pressure rollers (if used) do not heat any layer or layers of the HDI PCB apparatus above 80° C. According to some embodiments, the thermoset polymeric material or materials making up the dielectric layer do not cure or further cure as a result being fed through the hot or cold pressure rollers during the formation of the HDI PCB apparatus.

In some embodiments, only two layers of the HDI PCB apparatus are laminated upon each other at a time. In some embodiments, only three layers of the HDI PCB apparatus are laminated upon each other at a time. In some embodiments, the layers of the HDI PCB apparatus must be laminated through the hot or cold rollers two or more times before it is completed.

The rolls of each layer of the HDI PCB apparatus may include sheets of each respective layer. For example, a roll of a protective layer may include continuous, planar sheets of a protective material, a roll of a dielectric layer may include continuous, planar sheets of a dielectric material, a roll of a conductive layer may include continuous, planar sheets of a conductive material, a roll of a C-stage layer may include continuous, planar sheets of a C-stage material, and a roll of a supporting layer may include continuous, planar sheets of a supporting material.

For example, in an embodiment, first a roll of a conductive layer and a roll of a support layer may be laminated together over hot pressure rollers at a controlled temperature between about 80° C. and 120° C. and collected into a roll. Then, in a separate rolling process, a roll of the dielectric layer and a roll of the protective layer are passed through the hot pressure rollers together at a controlled temperature between about 80° C. and 120° C. with the already-formed laminate of the conductive layer and the support layer to form long sheets of the HDI PCB apparatus. Preferably, the layers of the completed HDI PCB apparatus have the same orientation as illustrated in FIG. 1, i.e. a protective layer on top of a dielectric layer on top of a conductive layer on top of a support layer. In embodiments where the C-stage layer is used, preferably the layers of the completed HCB PCB apparatus have the same orientation as illustrated in FIG. 3, i.e. a protective layer on top of a dielectric layer on top of a C-stage layer on top of a conductive layer on top of a support layer.

After the layers of HDI PCB apparatus are formed into long sheets, the sheets of HDI PCB apparatus are cut into pieces suitable for PCB manufacture. Pieces suitable for PCB manufacture may have a length by width dimension such as 13 inches by 19 inches, 17 inches by 19 inches, 19 inches by 25 inches, 22 inches by 25 inches, 23 inches by 26 inches, 18 inches by 24 inches, 20 inches by 26 inches, 21 inches by 24 inches, and the like. The individual cut pieces, in some embodiments may be drilled with tooling holes through all layers of each HDI PCB apparatus. The individual cut pieces of the HDI PCB apparatus may then be stored in boxes as kits or used immediately to make PCBs.

In another embodiment, a method for forming a HDI PCB apparatus may include the following steps. First, sheets from rolls of a protective layer, a dielectric layer, and a conductive layer may be laminated together in a heated or unheated nip roller and collected into a roll of a composite material. Then, sheets from the roll of the composite material may be laminated on top of sheets from a roll of a support layer in a heated nip roller.

In yet another embodiment, as illustrated in FIG. 10, a method for forming a HDI PCB apparatus 300 may include the following steps. First, sheets 305 from a roll of a protective layer 301, sheets 306 from a roll of a dielectric layer 302, sheets 307 from a roll of a conductive layer 303, and sheets 308 from a roll of a support layer 304 may be laminated together in a heated nip roller 309. The heated nip roller 309, through heat and pressure, bonds the layers together into long sheets of HDI PCB apparatus 310.

### Method for Forming a Z-Axis Interconnect in the Manufacture of a PCB

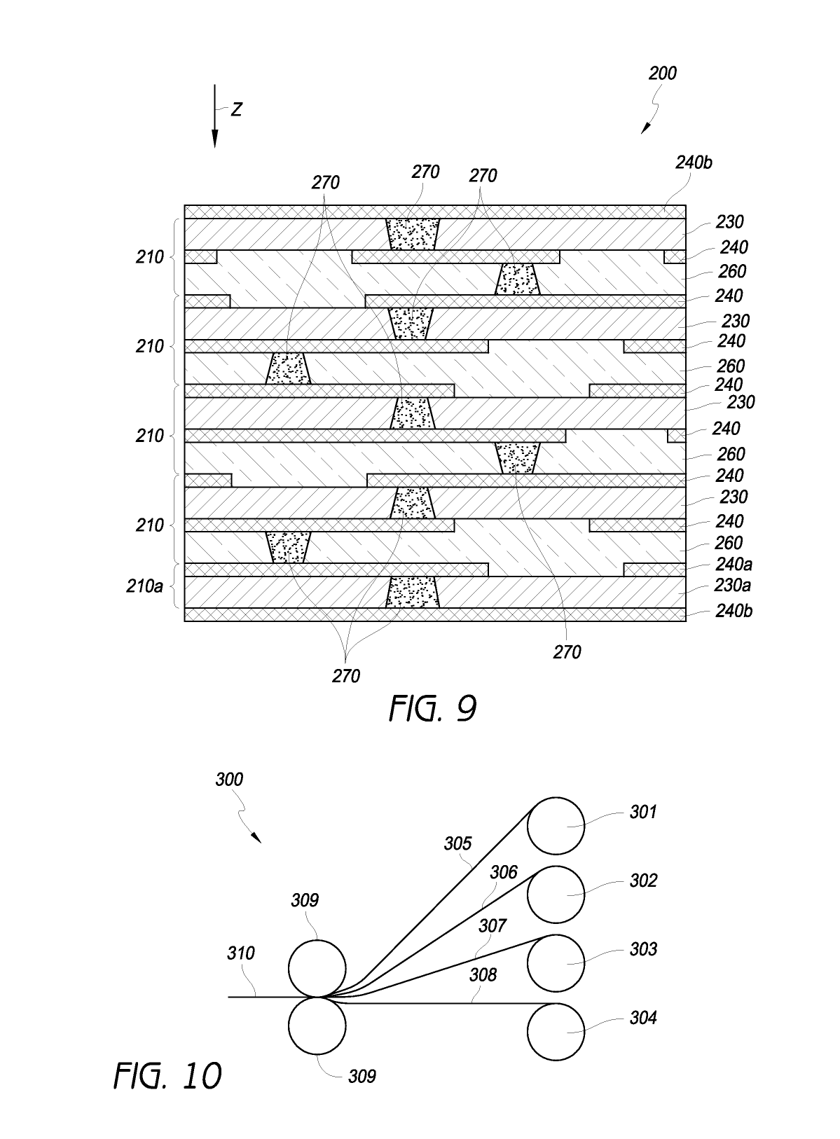

According to an embodiment, a method for forming an interconnect in at least one adjacent layer of a PCB is shown in FIGS. 4-9. By incorporating the HDI apparatus of this disclosure, multiple layers of HDI may be formed, up to 10 or more interconnect layers as shown in FIG. 9. As demonstrated in FIG. 4, a hole 6 is drilled through the protective layer 2 and dielectric layer 3 to the top surface of conductive layer 4. The drilling may occur via conventional drilling methods including, but not limited to, manual drilling and laser drilling. As is shown in FIG. 4, the drill hole may have a substantially conical shape, with a smaller diameter nearer to the bottom surface of the HDI PCB apparatus 1, and a larger diameter nearer to the top surface of the HDI PCB apparatus 1. However, in other embodiments, the drill hole may be substantially rectangular, square, or rounded in shape.

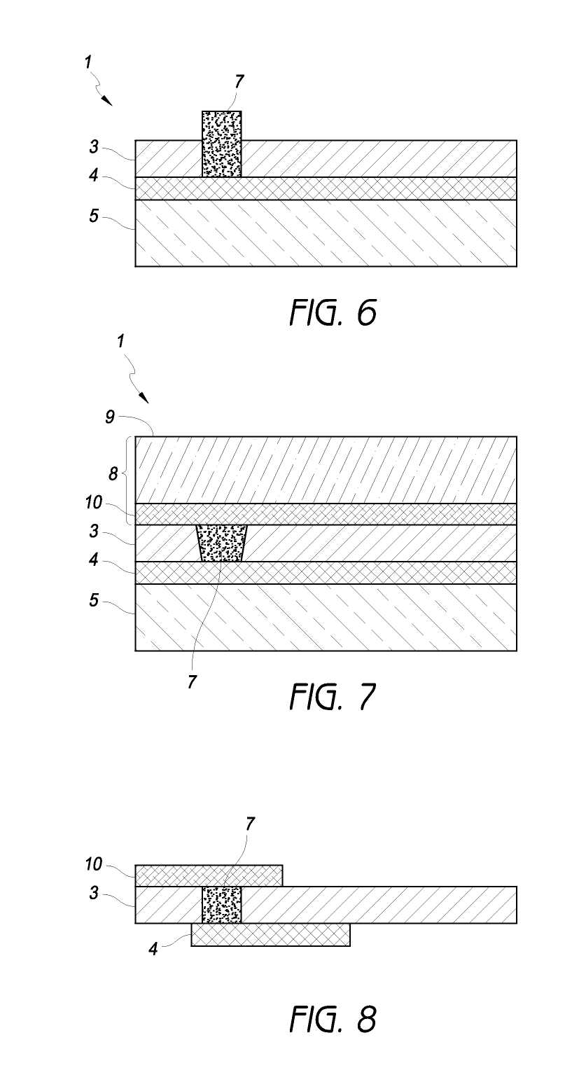

As illustrated in FIG. 5, a conductive paste or conductive ink 7 is applied to the hole 6. The conductive paste may comprise a suitable paste such as paste capable of being sintered. The paste may be capable of being sintered at relatively low temperatures, so as not to damage the other materials comprising the apparatus. The conductive ink may include inks containing silver, such as ORMET® 800, 700, or 500 series conductive inks. According to other applications, a non-sintering conductive paste may be used. Then, the conductive paste 7 and apparatus 1 are baked. As shown in FIG. 6, the protective layer 2 is then removed, leaving a portion of the paste 7 exposed.

As shown in FIG. 7, then a new layered system 8 is applied to apparatus 1. New layered system 8 comprises a second supporting layer 9 and a second conductive layer 10. In some embodiments, only a second conductive layer without a second supporting layer 9 is applied to apparatus 1. Preferably, the conductive layer 10 contacts conductive paste 7. According to an embodiment, the new layered system 8 is laminated (e.g. placed under heat and pressure in a lamination press) onto apparatus 1 to form a pre-core. As illustrated in FIG. 8, then the support layers 5, 9 may be removed because the pre-core now has structural integrity and can be handled and etched since the dielectric layer is cured. At this point, the user can remove the support layers 5 and 9, the conductive layers 4, 10 may be printed and etched to form a double-sided core. These layers may be laminated upon one another to form HDI PCBs. In some embodiments, the layers may be laminated upon other types of PCBs, not necessarily HDI PCBs, to form complex circuit boards.

According to the methods described herein, a double-sided core may be formed. However, the methods described herein may also be used to form a single sided core, by only applying a conductive material to one side of the dielectric layer.

The HDI PCBs formed according to this method advantageously allow a user to place a via wherever they would want to drill during formation of a PCB. Specifically, the vias in the HDI PCBs of this disclosure do not need to line up along the z axis between 3 or more conductive layers of a PCB.

Because layers of the HDI PCB may be laminated on to the PCB one layer at a time, the HDI PCBs formed may be advantageously tested for electrical shorts in each etched circuit layer as each single layer of PCB is formed and the z-axis interconnects are made. This may results in reduced scrap.

In some embodiments, all layers of the HDI PCB apparatus may be tooled together at the same time through the use of tooling holes. This embodiment advantageously reduces the number of lamination cycles that the HDI PCB apparatus needs to go through in its formation. Through the use of HDI PCB apparatuses with tooling holes, like those illustrated in FIG. 2, drilling accuracy may be ensured.

In some embodiments, a HDI PCB apparatus having the structure illustrated in FIG. 3 may be laminated on to one or more HDI PCB apparatus having the structure illustrated in FIG. 1. Also, a HDI PCB apparatus having the structure illustrated in FIG. 1 may be laminated on to one or more HDI PCB apparatus having the structure illustrated in FIG. 3. Desirably, a HDI PCB apparatus having the structure illustrated in FIG. 3, including the cap layer, is laminated on to the uppermost and lowermost layers of the PCB. Such an embodiment may exhibit beneficial properties such as a reduction in pad cratering.

### E. Additional Applications

A HDI PCB formed according to the methods described above may have several advantages. For example, the support layer may support the conductive and dielectric layers through the laser drilling, filling and drying processes. After lamination, alignment holes for circuit imaging may be drilled. Afterwards, a releasable adhesive or glue (if used) may allow for the support layer to be easily peeled off. The method described above results in a HDI PCB having a thin structure, and with a core with z-axis interconnects already built in.

### Printed Circuit Boards and Subassemblies

A printed circuit board may thus be formed with z-axis interconnects already formed within the HDI PCB layers, which are laminated upon one another. In some embodiments, up to 20 HDI PCB layers may be laminated upon one another to form a PCB. In some embodiments, up to 15 HDI PCB layers or up to 10 HDI PCB layers may be laminated upon one another to form a PCB. In some embodiments, the HDI PCB disclosed herein may be laminated onto non-any layer HDI PCBs and PCBs that include via that are copper plated as opposed to filled with conductive paste, thus forming a hybrid PCB having both HDI PCB layers and PCB layers according to known methods. PCBs for example, may comprise a core, that may or may not utilize any-layer HDI and additional layers may be laminated on to the PCB that do or do not use any-layer HDI.

An HDI PCB may be formed using the HDI PCB apparatus according to the following method. First one or more HDI PCB layers may be formed. Specifically, an HDI PCB apparatus having a protective layer disposed on a dielectric layer disposed on a first conductive layer disposed on a first support layer may be provided, then a via may be formed by laser drilling the via through the protective layer and the dielectric layer to the conductive layer. Then the protective layer may be removed and a second conductive layer may be laminated under heat and pressure on top of the dielectric layer and first conductive layers until the first dielectric layer cures, if the first electric layer is made of a thermoset material. In some embodiments, the second conductive layer may be supported by a second support layer. Then, the first support layer and the second support layer (if used) are removed and the first conductive layer and second conductive layers are etched. Then, a second dielectric layer may be nip laminated on to the first and/or the second conductive layer or layers. The second dielectric layer may then be laser drilled to form a via and the via formed may be filled with a conductive ink. This process may be repeated with other HDI PCB apparatuses in parallel to form multiple HDI PCB layers. Finally, the HDI PCB layers may be stacked upon one another so that the second dielectric layer of each HDI PCB layer engages a first or second conductive layer of the next HDI PCB layer. The stacked HDI PCB layers may then be laminated under heat and pressure to form an HDI PCB. When the HDI PCB layers are laminated together, the second dielectric layers may flow and then cure under heat and pressure to fill in any gaps between the second dielectric layers and the adjacent first dielectric layers. In some embodiments, an addition conductive layer or layers may be laminated on to the outermost surface or surfaces of the HDI PCB. According to other embodiments, an additional HDI PCB apparatus without a second dielectric layer may be laminated on to the outermost surface or surfaces of the HDI PCB. In some embodiments, both an additional HDI PCB apparatus without a second dielectric layer and an additional conductive layer may be laminated on to outermost surface or surfaces of the HDI PCB.

As illustrated in the embodiment of FIG. 9, an HDI PCB 200 comprises HDI PCB layers 210. The vertical or “z-axis” is illustrated in this FIGURE as Z. Each HDI PCB layer 210 includes a first dielectric layer 230 containing at least one filled via 270. The filled via 270 may be filled with a conductive ink. The first dielectric layer 230 contacts at least a portion of at least one etched conductive layer 240 and at least a portion of a second dielectric layer 260. The second dielectric layer 260 may contain at least one filled via 270. The second dielectric layer 260 may contact at least a portion of at lest one conductive layer 240 and at least a portion of a first dielectric layer 230. As illustrated in FIG. 9, an additional HDI PCB layer 210a may be laminated on to the bottom of an HDI PCB layer 210. The HDI PCB layer 210a may include a first dielectric layer 230a and an etched conductive layer 240a. The HDI PCB 200 may also include conductive layers 240b laminated on the top side and the bottom side of the HDI PCB 200. In such as an embodiment, where the HDI PCB apparatus was used to create HDI PCB layers 210 or 210a, the support layer would have been previously removed in the creation of the HDI PCB 200.

Desirably, the filled vias 270 contact and electrically connect two etched conductive layers 240 or connect at least one etched conductive layer 240 with a conductive layer 240a. As is illustrated in FIG. 9, vias may connect etched conductive layers, even though they are not in alignment along the z-axis. This is sometimes referred to as “any-layer HDI.” In some embodiments, the second dielectric layer 260 may not include vias.

As is shown in FIG. 9, a distinctive characteristic of multiple-layer PCBs formed according to the disclosure herein are the orientation of the via holes drilled in the cross-sectional layers of the PCB. Specifically, as HDI PCB apparatus layers are laminated upon one another and vias are drilled, the orientation of the via holes may alternate, the via hole or holes in one HDI PCB apparatus layer may have a smaller diameter at the bottom-facing surface of the layer, then the via hole or holes drilled in the adjacent engaged HDI PCB apparatus layer or layers may have a smaller via hole at the top-facing surface of the layer. When a PCB is manufactured, such as the PCB in FIG. 9, the support layer of the HDI PCB apparatus would have been previously removed.

According to other embodiments, vias may not be present in every dielectric layer. Secondly, the vias may not necessary use a conductive paste or conductive ink, some of the vias could be copper plated. In another embodiment, the board could be made with double-sided cores, which are two conductive layers separated by a dielectric layer. One could have a series of double sided cores that could be laminated together to achieve the any-layer HDI PCB of FIG. 9 and it would be necessary to separate each double sided core with a dielecletic layer. Alternatively, the HDI PCB of FIG. 9 could be constructed from a combination of double-layer cores and single-layer cores, wherein a single-layer core is comprised of a single layer of conductive materials laminated to a dielectric layer.

The PCB of FIG. 9 can be manufactured using any combination of any-layer HDI method or non any-layer HDI methods as well as any combination of traditional PCB methods and HDI methods. In some embodiments a C-stage layer and a conductive layer (e.g. a cap layer) may be laminated on the top surface and/or the bottom surface of the HDI PCB.

In some embodiments, a subassembly may use the HDI PCB apparatus in one or more layers of the subassembly. A subassembly may be formed including at least one dielectric layer, at least one etched conductive layer disposed on the dielectric layer, at least one via, filled with a conductive paste. An additional HDI PCB apparatus may then be laminated on top of the subassembly, wherein the protective layer has already been removed and the dielectric layer contacts the dielectric layer of the subassembly as well as the etched conductive layer. Thus, in such as assembly, a support layer is disposed on top of a conductive layer, which is disposed on top of a dielectric layer, which is disposed on top of the etched subassembly. When the new HDI PCB layer is ready to be etched, the support layer may be removed, revealing the conductive layer underneath.

### Supplemental Protective Layer

In some embodiments, a supplemental protective layer may be adhered to subassemblies of the HDI PCB apparatus after they are drilled and vias are formed, but before they are fully formed into more complex PCBs. For example, several layers of a PCB may be manufactured and laminated upon one another as described herein, but lamination of additional layers may be desirably done at a later point. This uncompleted PCB may be referred to as a subassembly.

In embodiments where a supplemental protective layer is used, the supplemental protective layer may comprise a plastic film, such as polyethylene terephthalate. The plastic film may have a thin, low-tack pressure sensitive adhesive adhered to the bottom surface of the plastic film. The adhesive may be any suitable adhesive such as an epoxy-based resin, an acrylic adhesive, and the like. In some embodiments, the low tack adhesive does not require heat to bond to the conductive layer.

The supplemental protective layer may be laminated onto a PCB subassembly comprising two or more pre-drilled HDI PCB apparatus layers. According to some embodiments, the supplemental protective layer may be laminated onto a PCB subassembly comprising five or more pre-drilled HDI PCB apparatus layers, seven or more pre-drilled HDI PCB apparatus layers, and the like. In some embodiments, the supplemental protective layer may be adhered to PCB subassemblies that do not include the HDI PCB apparatus as described herein, and may include PCB subassemblies known to those of skill in the art. Preferably, the supplemental protective layer is laminated to the side of the PCB on which a conductive layer is exposed.

After the supplemental protective layer is laminated on to the subassembly, it protects the subassembly from dirt and debris that could negatively impact the subassembly during storage and cause defects in the subassembly. Specifically, the supplemental protective layer, once laminated on the subassembly, may help eliminate resin spots and may prevent pits and dents in the surface of the conductive layer. The supplemental protective layer, once laminated on to a subassembly may also improve a user's ability to handle sheets of the subassemblies without causing defects to the surface of the subassembly.

After the supplemental protective layer is laminated on to the subassembly, it may later be removed in order to reveal a clean surface of the PCB through peeling off the supplemental protective layer. Preferably the supplemental protective layer leaves behind no adhesive residue when it is removed.

Although the foregoing description has shown, described and pointed out the fundamental novel features of the embodiments disclosed herein, it will be understood that various omissions, substitutions, and changes in the form of the detail of the apparatus as illustrated, as well as the uses thereof, may be made by those skilled in the art, without departing from the spirit or scope of the present invention. Consequently, the scope of the present application should not be limited to the foregoing discussion, but should be defined by the appended claims.

What is claimed is:

1. A HDI PCB apparatus comprising:
at least one layer of aluminum;
at least one layer of copper;
at least one dielectric layer; and
at least one protective layer;
wherein the at least one layer of aluminum engages the at least one layer of copper, the at least one layer of copper engages the at least one dielectric layer, and the at least one dielectric layer engages the at least one protective layer.

2. The HDI PCB apparatus of claim 1, where the at least one layer of aluminum has a thickness between about 0.003 inches and about 0.002 inches.

3. The HDI PCB apparatus of claim 1, where the at least one layer of copper has a thickness between about 15 microns and about 60 microns.

4. The HDI PCB apparatus of claim 1, where the at least one dielectric layer has a thickness between about 0.0008 inches and about 0.008 inches.

5. The HDI PCB apparatus of claim 1, where the at least one protective layer has a thickness between about 0.0007 inches and about 0.003 inches.

6. The HDI PCB apparatus of claim 1, where the dielectric layer comprises a B-stage resin.

7. The HDI PCB apparatus of claim 6, where the dielectric layer comprises a benzoxazine-based resin.

8. A HDI PCB apparatus comprising:
at least one layer of aluminum;
at least one layer of copper;
at least one cured dielectric layer;
at least one B-stage dielectric layer; and
at least one protective layer;
wherein the at least one layer of aluminum engages the at least one layer of copper, the at least one layer of copper engages the at least one cured dielectric layer, the at least one cured dielectric layer engages the at least one B-stage dielectric layer, and the at least one B-stage dielectric layer engages the at least one protective layer.

9. A method for forming a z-axis interconnect comprising:
providing a z-axis interconnect apparatus comprising at least one first support layer, at least one conductive layer, at least one dielectric layer, and at least one protective layer;
drilling a hole through the at least one protective layer and the at least one support layer;
filling the hole with a conductive ink;
baking the apparatus and the conductive ink;
laminating a second apparatus comprising a second conductive layer and a second support layer on the z-axis interconnect apparatus;
removing the first support layer and the second support layer; and
etching a circuit on the first conductive layer and the second conductive layer.

10. A method for forming a HDI PCB apparatus comprising:
providing a roll of a support material;
providing a roll of a conductive material comprising sheets of the conductive material;
providing a roll of a dielectric material comprising sheets of the dielectric material;
providing a roll of a support material comprising sheets of the support material;
rolling the sheets of the roll of a support material, the roll of a conductive material, a roll of a dielectric material, and the roll of the support material together to form long sheets of the HDI PCB apparatus; and
cutting the long sheets of the HDI PCB apparatus into single sheets of the HDI PCB apparatus.
